(19) United States
(12) Patent Application Publication
(10) Pub. No.: US 2025/0221188 A1
(43) Pub. Date: Jul. 3, 2025

(54) DISPLAY APPARATUS

(71) Applicant: LG Display Co., Ltd., Seoul (KR)

(72) Inventor: Jongmoo HA, Gimpo-si (KR)

(21) Appl. No.: 18/679,058

(22) Filed: May 30, 2024

(30) Foreign Application Priority Data
Dec. 29, 2023 (KR) 10-2023-0196633

(51) Int. Cl. H10K 59/131; H10K 59/40

(52) U.S. Cl. CPC H10K 59/131; H10K 59/40

(57) ABSTRACT

Provided is a display apparatus. The display apparatus having a substrate including a display area and a non-display area adjacent to the display area. The display apparatus includes a pixel disposed in the display area of the substrate. The pixel includes at least one transistor and a light emitting diode. The display apparatus includes a touch sensor unit disposed on the pixel. The touch sensor unit includes at least one touch electrode. The display apparatus includes a common power line disposed in the non-display area of the substrate and electrically connected to the light emitting diode. The display apparatus includes a gate driving circuit disposed in the non-display area of the substrate. The common power line and the gate driving circuit may overlap each other in at least a part of the non-display area from a plan view.

### CROSS-REFERENCE TO RELATED APPLICATIONS

This application claims the priority of Korean Patent Application No. 10-2023-0196633 filed on Dec. 29, 2023, in the Korean Intellectual Property Office, the disclosure of which is incorporated herein by reference.

### BACKGROUND

### Technical Field

The present disclosure relates to a display apparatus, and more particularly, to a display apparatus with a reduced bezel area.

### Description of the Related Art

With the advancement of technologies in the modern society, a display apparatus has been used in various forms to provide users with information. The display apparatus is also included in various electronic devices, which receive a user input and use advanced technologies to provide information in response to the received input, as well as an electronic display board that unilaterally transfers visual information.

Meanwhile, in the display apparatus, a minimum bezel area, e.g., a non-display area needs to be provided to secure reliability such as anti-moisture permeation. However, since the non-display area does not display an image, there is a demand to increase screen immersion and enhance aesthetic sense by increasing the size of a display area and decreasing the size of the non-display area.

### BRIEF SUMMARY

Various embodiments of the present disclosure provide a display apparatus with a reduced or minimized non-display area which is a bezel area.

Various embodiments of the present disclosure provide a display apparatus in which a resistance of a common power line can be reduced.

Technical benefits of the exemplary embodiment of the present disclosure are not limited to the above-mentioned benefits, and other benefits, which are not mentioned above, can be clearly understood by those skilled in the art from the following descriptions.

A display apparatus according to an exemplary embodiment of the present disclosure includes a substrate including a display area and a non-display area enclosing the display area, a pixel disposed in the display area of the substrate and including at least one transistor and a light emitting diode, a touch sensor unit disposed on the pixel and including at least one touch electrode, a common power line disposed in the non-display area of the substrate and connected to the light emitting diode, and a gate driving circuit disposed in the non-display area of the substrate. The common power line and the gate driving circuit may overlap each other in at least a part of the non-display area.

Other detailed matters of the exemplary embodiments are included in the detailed description and the drawings.

According to the present disclosure, a common power line and a gate driving circuit are disposed to overlap each other in a non-display area. Thus, the size of the non-display area can be reduced or minimized, and the width of a bezel can be reduced or minimized.

According to the present disclosure, a resistance of the common power line is reduced through a routing line disposed in the non-display area. Thus, it is possible to suppress an image quality defect, such as blurring, caused by a voltage change in the common power line.

According to the present disclosure, the routing line connected to the common power line in the non-display area is disposed to overlap the common power line. Thus, a resistance of the common power line can be reduced without increasing the width of the common power line or increasing the width of the bezel.

According to the present disclosure, a potential defect, such as an image quality defect, of a display apparatus can be reduced or minimized. Therefore, a lifetime of the display apparatus can be improved, and the display apparatus can be driven with low power consumption in terms of production energy saving.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view of a display apparatus according to an exemplary embodiment of the present disclosure;

FIG. 2 is a circuit diagram showing an example of a pixel of the display apparatus according to an exemplary embodiment of the present disclosure;

FIG. 3 is an enlarged view illustrating an example of a portion EA of FIG. 1;

FIG. 4 is a cross-sectional view taken along the line I-I′ of FIG. 1;

FIG. 5 is a cross-sectional view taken along the line II-II′ of FIG. 1;

FIG. 6 is a cross-sectional view taken along the line III-III′ of FIG. 1;

FIG. 7 is a cross-sectional view of a display apparatus according to another exemplary embodiment of the present disclosure;

FIG. 8 is a plan view of a display apparatus according to yet another exemplary embodiment of the present disclosure; and

FIG. 9 is a cross-sectional view taken along the line IV-IV′ of FIG. 8.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, numbers, number of elements, and the like illustrated in the accompanying drawings for describing the exemplary embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” other element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

The features of various embodiments of the present disclosure can be partially or entirely adhered to or combined with each other and can be interlocked and operated in technically various ways, and the embodiments can be carried out independently of or in association with each other.

Hereinafter, a display apparatus according to exemplary embodiments of the present disclosure will be described in detail with reference to accompanying drawings.

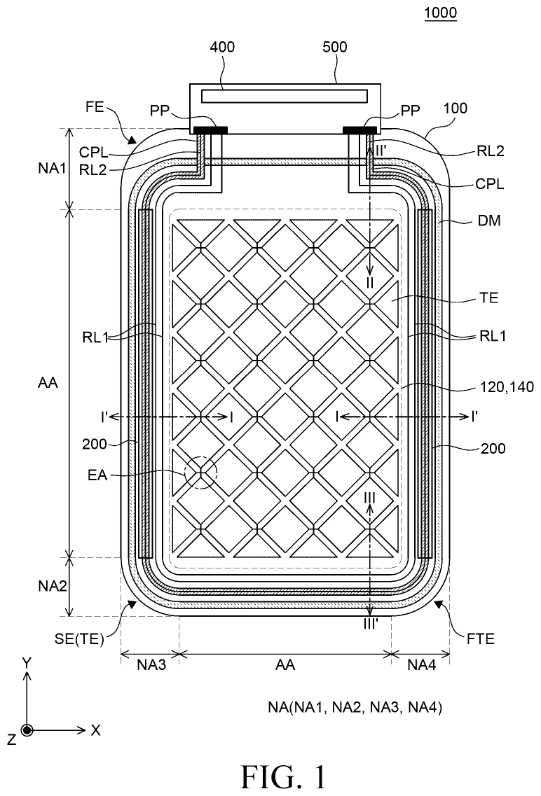

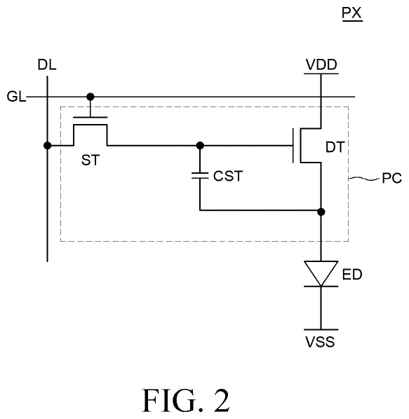

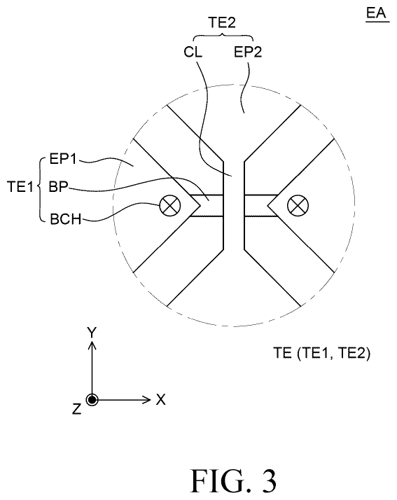

FIG. 1 is a plan view of a display apparatus according to an exemplary embodiment of the present disclosure. FIG. 2 is a circuit diagram showing an example of a pixel of the display apparatus according to an exemplary embodiment of the present disclosure. FIG. 3 is an enlarged view illustrating an example of a portion EA of FIG. 1.

A display apparatus 1000 according to an exemplary embodiment of the present disclosure may be an electroluminescent display apparatus. The electroluminescent display apparatus may be an organic light emitting diode display apparatus, a quantum-dot light emitting diode display apparatus, or an inorganic light emitting diode display apparatus.

Hereinafter, for the convenience of description, a transverse direction on the plane is defined as a first direction X and a longitudinal direction on the plane is defined as a second direction Y. Also, the normal direction of a plane defined by the first direction X and the second direction Y, e.g., a thickness direction of the display apparatus 1000, may be defined as a third direction Z.

Referring to FIG. 1, the display apparatus 1000 according to an exemplary embodiment of the present disclosure may include a substrate 100, a pixel array layer 120, a touch sensor unit 140 (also referred to as a touch sensor 140 or a touch sensor circuit 140), and a common power line CPL. In some exemplary embodiments, the display apparatus 1000 may further include an encapsulation layer disposed between the pixel array layer 120 and the touch sensor unit 140.

The substrate 100 is a base layer, and may contain an insulating material. The substrate 100 may contain a transparent material. For example, the substrate 100 may contain glass or plastic.

Meanwhile, FIG. 1 illustrates that the substrate 100 has a rounded rectangular shape, each of whose corner portions is rounded with a certain curvature radius. However, the shape of the substrate 100 is not limited thereto. The substrate 100 may have various shapes.

The substrate 100 may include a display area AA and a non-display area NA.

The display area AA may be defined as an area in which images are displayed. The display area AA may have a rectangular shape, a rounded rectangular shape, each of whose corner portions is rounded with a certain curvature radius, or a non-rectangular shape having at least six sides, on a plane. In this case, the display area AA having a non-rectangular shape may include at least one protrusion or at least one notch portion. However, the shape of the display area AA is not limited thereto. The shape of the display area AA may be widely varied.

The non-display area NA may be disposed to enclose the display area AA, and may be defined as an area in which no image is displayed or a peripheral area.

The non-display area NA may include a first non-display area NA1 disposed at a first edge FE of the substrate 100 and a second non-display area NA2 disposed at a second edge SE of the substrate 100 opposing the first non-display area NA1. The non-display area NA may also include a third non-display area NA3 disposed at a third edge TE of the substrate 100 and a fourth non-display area NA4 disposed at a fourth edge FTE of the substrate 100 opposing the third non-display area NA3. In some embodiments, the third edge TE of the substrate 100 and the second edge SE of the substrate 100 may refer to the same edge of the substrate 100. For example, the first non-display area NA1 may be an upper edge area of the substrate 100, and the second non-display area NA2 may be a lower edge area of the substrate 100. Also, the third non-display area NA3 may be a left edge area of the substrate 100, and the fourth non-display area NA4 may be a right edge area of the substrate 100. However, the present disclosure is not limited thereto. That is, in other embodiments, the third edge TE of the substrate 100 may be opposite of the first edge FE of the substrate 100 and diagonal to the second edge SE of the substrate 100. Similarly, the fourth edge FTE of the substrate 100 may be adjacent to the second edge SE and the third edge TE of the substrate 100 and diagonal to the first edge FE of the substrate 100.

The pixel array layer 120 may be provided in the display area AA of the substrate 100. For example, the pixel array layer 120 may include a plurality of gate lines, a plurality of data lines, and a plurality of pixels.

The plurality of gate lines included in the pixel array layer 120 may extend along the first direction X and may be disposed in the second direction Y. For example, the display area AA of the substrate 100 may include the plurality of gate lines disposed in parallel with the first direction X so as to be spaced apart from each other in the second direction Y.

The plurality of data lines included in the pixel array layer 120 may extend along the second direction Y and may be disposed in the first direction X. For example, the display area AA of the substrate 100 may include the plurality of data lines disposed in parallel with the second direction Y so as to be spaced apart from each other in the first direction X.

Each of the plurality of pixels included in the pixel array layer 120 is disposed in a pixel area defined in the display area AA of the substrate 100. Also, each of the plurality of pixels may be electrically connected to at least one of the plurality gate lines and at least one of the plurality of data lines. Herein, the pixel area may be defined at an intersection between a gate line and a data line, but is not limited thereto.

Each pixel may include a plurality of sub-pixels which emits light of different colors from each other. For example, each pixel may implement blue, red, and green colors by using three sub-pixels, but is not limited thereto. In some cases, the pixel may further include a sub-pixel for implementing white color.

In the pixel, an area implementing blue may be referred to as a blue sub-pixel, an area implementing red may be referred to as a red sub-pixel, and an area implementing green may be referred to as a green sub-pixel.

Referring to FIG. 2, each of a plurality of pixels PX included in the pixel array layer 120 may include a pixel circuit PC electrically connected to a gate line GL and a data line DL, and a light emitting diode (LED) ED connected to the pixel circuit PC.

A plurality of transistors DT and ST shown in FIG. 2 may contain at least one of amorphous silicon, polycrystalline silicon, and oxide semiconductor, such as IGZO. A first electrode or a second electrode of each transistor may be a source electrode or a drain electrode. For example, the first electrode may be a source electrode, and the second electrode may be a drain electrode. For another example, the first electrode may be a drain electrode, and the second electrode may be a source electrode.

The pixel circuit PC may control a driving current flowing from a first power line, which supplies a first power voltage VDD, e.g., a high potential power voltage, to a second power line, which supplies a second power voltage VSS, e.g., a low potential power voltage, through the LED ED based on a data signal supplied from the data line DL in response to a gate signal supplied from the gate line GL.

The pixel circuit PC may include the driving transistor DT, the switching transistor ST, and a storage capacitor CST.

The driving transistor DT and the storage capacitor CST may be connected to the switching transistor ST. A first electrode of the driving transistor DT may be connected to the first power line which supplies the first power voltage VDD.

The switching transistor ST may be connected to the gate line GL to receive the gate signal. The switching transistor ST may be turned on or off by the gate signal. A first electrode of the switching transistor ST may be connected to the data line DL. In this case, the data signal may be supplied to a gate electrode of the driving transistor DT through the switching transistor ST in response to turning-on of the switching transistor ST.

The storage capacitor CST may be disposed between the gate electrode and a second electrode of the driving transistor DT. The storage capacitor CST can maintain a signal, e.g., a data signal, applied to the gate electrode of the driving transistor DT for one frame.

The LED ED may be connected between the pixel circuit PC and the second power line which supplies the second power voltage VSS. For example, the LED ED may include a first electrode connected to the pixel circuit PC, e.g., the driving transistor DT, and a second electrode connected to the second power line. The LED ED may emit light in response to the driving current supplied from the pixel circuit PC, e.g., the driving transistor DT.

Referring to FIG. 1, the driving current supplied to the LED ED may flow to the second power line which supplies the second power voltage VSS, e.g., the common power line CPL.

The common power line CPL may have a constant line width and may be disposed to enclose at least a part of the display area AA of the substrate 100. For example, the common power line CPL may be disposed in at least a part of the first non-display area NA1 and in the second to fourth non-display areas NA2, NA3 and NA4 so as to enclose at least a part of the display area AA. For example, one end of the common power line CPL may be disposed on one side of the first non-display area NA1, and the other end of the common power line CPL may be disposed on the other side of the first non-display area NA1. The common power line CPL may extend from one side of the first non-display area NA1 to the third non-display area NA3, the second non-display area NA2, the fourth non-display area NA4, and the other side of the first non-display area NA1. Therefore, the common power line CPL may be disposed in a “U” shape, at least a part of which is opened, in a plan view, but is not limited thereto.

The touch sensor unit 140 may be disposed on the pixel array layer 120. The touch sensor unit 140 may sense a touch according to a touch object, e.g., a touch position and/or a touch intensity. Herein, the touch object may include a user's finger or a touch pen, but is not limited thereto.

The touch sensor unit 140 may include a touch electrode part, a first routing part, and a second routing part. Herein, the first routing part may also be defined as a touch routing part, and the second routing part may also be defined as a dummy pattern unit. The exemplary embodiments of the present disclosure are not limited by the terminologies used herein.

The touch electrode part of the touch sensor unit 140 may include a plurality of touch electrodes TE disposed in the display area AA of the substrate 100.

The touch electrodes TE will be described in more detail with reference to FIG. 3. The plurality of touch electrodes TE may include a plurality of first touch electrodes TE1 and a plurality of second touch electrodes TE2.

The plurality of first touch electrodes TE1 may extend along the first direction X and may be disposed in the display area AA of the substrate 100 so as to be spaced apart from each other in the second direction Y. The plurality of first touch electrodes TE1 may serve as touch sensing electrodes or touch driving electrodes to sense a touch position of the touch object.

Each of the plurality of first touch electrodes TE1 may include a plurality of first electrode patterns EP1 and a plurality of bridge patterns BP.

The plurality of first electrode patterns EP1 may be disposed in the display area AA of the substrate 100 so as to be spaced apart from each other in the first direction X.

The plurality of bridge patterns BP may be disposed in the display area AA of the substrate 100 so as to be spaced apart from each other in the first direction X. Also, each of the plurality of bridge patterns BP may electrically connect two first electrode patterns EP1 adjacent to each other in the first direction X. Each of the plurality of bridge patterns BP is disposed to overlap a space between the two first electrode patterns EP1 adjacent to each other in the first direction X. Thus, each of the plurality of bridge patterns BP can suppress a short circuit at an intersection between the first touch electrode TE1 and the second touch electrode TE2.

One side of each of the plurality of bridge patterns BP is electrically connected to one first electrode pattern EP1 disposed on one side of the two first electrode patterns EP1 adjacent to each other in the first direction X. The other side of each of the bridge patterns BP is electrically connected to the other first electrode pattern EP1 disposed on the other side of the two first electrode patterns EP1 adjacent to each other in the first direction X. For example, each of the plurality of bridge patterns BP may be formed in a straight line shape, but is not limited thereto. Each of the plurality of bridge patterns BP may be formed to have various shapes, such as a curved shape, an angled shape, or a mesh shape, to electrically connect the two first electrode patterns EP1 adjacent to each other in the first direction X.

The plurality of second touch electrodes TE2 may extend along the second direction Y and may be disposed in the display area AA of the substrate 100 so as to be spaced apart from each other in the first direction X. Thus, the plurality of second touch electrodes TE2 may be electrically insulated from the plurality of first touch electrodes TE1. The plurality of second touch electrodes TE2 may serve as touch driving electrodes or touch sensing electrodes to sense a touch position of the touch object.

Each of the plurality of second touch electrodes TE2 may include a plurality of second electrode patterns EP2 and a plurality of connection lines CL.

The plurality of second electrode patterns EP2 may be disposed in the display area AA of the substrate 100 so as to be spaced apart from each other in the second direction Y.

Each of the plurality of connection lines CL may be disposed between two second electrode patterns EP2 adjacent to each other in the second direction Y to electrically connect the two second electrode patterns EP2 adjacent to each other in the second direction Y. The plurality of connection lines CL may be disposed on the same layers as the plurality of second electrode patterns EP2, respectively. For example, a connection line CL and a second electrode pattern EP2 may be integrally formed. The plurality of connection lines CL may be disposed to intersect the plurality of bridge patterns BP, respectively.

In some exemplary embodiments, the plurality of bridge patterns BP of the first touch electrode TE1 may be changed to the plurality of connection lines CL of the second touch electrode TE2. Also, the plurality of connection lines CL of the second touch electrode TE2 may be changed to the plurality of bridge patterns BP of the first touch electrode TE1.

The touch sensor unit 140 may include a first touch electrode layer including the plurality of bridge patterns BP and a second touch electrode layer including the plurality of first electrode patterns EP1 and the plurality of second touch electrodes TE2. The touch sensor unit 140 may also include a touch insulating layer disposed between the first touch electrode layer and the second touch electrode layer. Herein, the first touch electrode layer may be disposed under or on the second touch electrode layer with the touch insulating layer interposed therebetween. For example, the touch sensor unit 140 may include a first touch electrode layer including the plurality of bridge patterns BP, a touch insulating layer disposed on the first touch electrode layer, and a second touch electrode layer disposed on the touch insulating layer and including the plurality of first touch electrodes TE1 and the plurality of second touch electrodes TE2. For another example, the touch sensor unit 140 may include a first touch electrode layer including the plurality of first touch electrodes TE1 and the plurality of second touch electrodes TE2, a touch insulating layer disposed on the first touch electrode layer, and a second touch electrode layer disposed on the touch insulating layer and including the plurality of bridge patterns BP.

The touch insulating layer include bridge contact holes BCH respectively disposed in overlap areas of the first electrode patterns EP1 and the bridge patterns BP. Accordingly, each of the plurality of bridge patterns BP is electrically connected to one side and the other side of the corresponding first electrode pattern EP1 through the bridge contact hole BCH provided in the touch insulating layer. Thus, each of the plurality of bridge patterns BP electrically connects the two first electrode patterns EP1 adjacent to each other in the first direction X.

Each of the plurality of first touch electrodes TE1 and the plurality of second touch electrodes TE2 may have a mesh structure in which metal lines having very small line widths intersect each other. Herein, each of the metal lines may be configured by a single layer or a multi-layered structure made of a conductive material, such as molybdenum (Mo), silver (Ag), titanium (Ti), copper (Cu), aluminum (Al), titanium/aluminum/titanium (Ti/Al/Ti) or molybdenum/aluminum/molybdenum (Mo/Al/Mo), but is not limited thereto.

Each of the plurality of first electrode patterns EP1 and the plurality of second electrode patterns EP2 may have a polygonal shape, for example, a rhombic shape, in a plan view. In this case, each of the plurality of electrode patterns EP1 and EP2 disposed along edge portions of the display area AA may have a triangular shape. Each of the plurality of first electrode patterns EP1 and the plurality of second electrode patterns EP2 may be simultaneously prepared by a process of forming mesh-shaped metal lines intersecting each other, and a process of cutting the metal lines disposed on touch electrode boundary areas preset on the display area AA to thereby provide the plurality of first electrode patterns EP1, the plurality of second electrode patterns EP2, and the plurality of connection lines CL.

The display apparatus 1000 according to an exemplary embodiment of the present disclosure may sense a touch by using a mutual capacitance between the first touch electrode TE1 and the second touch electrode TE2. The mutual capacitance is mainly generated in an outer portion of each of the first touch electrode TE1 and the second touch electrode TE2 adjacent to each other with a touch boundary area interposed therebetween. Accordingly, in the display apparatus 1000, cut portions of metal lines positioned on the outer portion of each of the first touch electrode TE1 and the second touch electrode TE2 are formed as protrusions to increase the area or length of each outer portion of the first touch electrode TE1 and the second touch electrode TE2. Thus, it is possible to increase the mutual capacitance generated in the touch boundary area or sensing area between the first touch electrode TE1 and the second touch electrode TE2. Accordingly, it is possible to improve a touch sensitivity.

The first routing part of the touch sensor unit 140 may be electrically connected to a touch electrode TE disposed in the non-display area NA of the substrate 100 and included in the touch sensor unit. For example, the first routing part may include a plurality of first routing lines RL1.

Each of the plurality of first routing lines RL1 may be disposed to enclose at least a part of the display area AA of the substrate 100. For example, each of the plurality of first routing lines RL1 may be disposed in at least a part of the first non-display area NA1 and in the second to fourth non-display areas NA2, NA3 and NA4.

Some of the plurality of first routing lines RL1 may be electrically connected to the plurality of first touch electrodes TE1 included in the touch sensor unit. Also, the others of the plurality of first routing lines RL1 may be electrically connected to the plurality of second touch electrodes TE2 included in the touch sensor unit.

For example, each of the plurality of first routing lines RL1 electrically connected to the plurality of first touch electrodes TE1 may extend from the first non-display area NA1 to the third non-display area NA3. Also, each of the plurality of first routing lines RL1 electrically connected to the plurality of first touch electrodes TE1 may be connected one-to-one to first touch electrodes TE1 disposed on one side of the display area AA, e.g., one side adjacent to the third non-display area NA3, among the plurality of first touch electrodes TE1 included in the touch sensor unit. Further, each of the plurality of first routing lines RL1 electrically connected to the plurality of second touch electrodes TE2 may extend from the first non-display area NA1 to the fourth non-display area NA4 and the second non-display area NA2. Furthermore, each of the plurality of first routing lines RL1 electrically connected to the plurality of second touch electrodes TE2 may be connected one-to-one to second touch electrodes TE2 disposed on another side of the display area AA, e.g., one side adjacent to the second non-display area NA2, among the plurality of second touch electrodes TE2 included in the touch sensor unit.

For another example, each of the plurality of first routing lines RL1 electrically connected to the plurality of first touch electrodes TE1 may extend from the first non-display area NA1 to the fourth non-display area NA4. Also, each of the plurality of first routing lines RL1 electrically connected to the plurality of first touch electrodes TE1 may be connected one-to-one to first touch electrodes TE1 disposed on one side of the display area AA, e.g., one side adjacent to the fourth non-display area NA4, among the plurality of first touch electrodes TE1 included in the touch sensor unit. Further, each of the plurality of first routing lines RL1 electrically connected to the plurality of second touch electrodes TE2 may extend from the first non-display area NA1 to the third non-display area NA3 and the second non-display area NA2. Furthermore, each of the plurality of first routing lines RL1 electrically connected to the plurality of second touch electrodes TE2 may be connected one-to-one to second touch electrodes TE2 disposed on another side of the display area AA, e.g., one side adjacent to the second non-display area NA2, among the plurality of second touch electrodes TE2 included in the touch sensor unit.

However, the above-described disposition of the plurality of first routing lines RL1 and connection relationship between the plurality of first routing lines RL1 and the plurality of touch electrodes TE1 and TE2 are just an example. The present disclosure is not limited thereto.

Meanwhile, for the convenience of description, FIG. 1 illustrates that two routing lines RL1 are disposed on the substrate 100. However, the number of the plurality of first routing lines RL1 is not limited thereto. For example, the plurality of first routing lines RL1 may be disposed on the substrate 100 so as to correspond in number to the plurality of touch electrodes TE1 and TE2 according to the above-described connection relationship between the plurality of first routing lines RL1 and the plurality of touch electrodes TE1 and TE2. For example, when the first touch electrodes TE1 are disposed on n (n is an integer greater than 0) number of rows along the second direction Y in the display area AA, the number of first routing lines RL1 electrically connected to the plurality of first touch electrodes TE1 may be n. Also, when the second touch electrodes TE2 are disposed on m (m is an integer greater than 0) number of columns along the first direction X in the display area AA, the number of first routing lines RL1 electrically connected to the plurality of second touch electrodes TE2 may be m.

The first routing lines RL1 included in the first routing part may be made of the same material and provided on the same layer as the plurality of touch electrodes TE1 and TE2 included in the touch electrode layer. For example, the first routing lines RL1 may be formed by the same process as the plurality of touch electrodes TE1 and TE2. Accordingly, the first routing part may be formed together with the touch electrode layer without any additional process. However, the present disclosure is not limited thereto.

The second routing part of the touch sensor unit 140 may include a second routing line RL2. In the present disclosure, the second routing line RL2 may also be defined as a dummy pattern.

The second routing line RL2 may be provided to overlap the common power line CPL disposed along the second to fourth non-display areas NA2, NA3 and NA4 of the substrate 100, and may be electrically connected to the common power line CPL.

The second routing line RL2 may have a constant line width and may be disposed to enclose at least a part of the display area AA of the substrate 100. For example, the second routing line RL2 may be disposed in at least a part of the first non-display area NA1 and in the second to fourth non-display areas NA2, NA3 and NA4 so as to enclose at least a part of the display area AA. For example, one end of the second routing line RL2 may be disposed on one side of the first non-display area NA1, and the other end of the second routing line RL2 may be disposed on the other side of the first non-display area NA1. The second routing line RL2 may extend from one side of the first non-display area NA1 to the third non-display area NA3, the second non-display area NA2, the fourth non-display area NA4, and the other side of the first non-display area NA1. Therefore, the second routing line RL2 may be disposed in a “U” shape, at least a part of which is opened, in a plan view, but is not limited thereto.

The second routing line RL2 may be provided to overlap the common power line CPL from a plan view. Also, the second routing line RL2 may be electrically connected to the common power line CPL in a contact area which is a part of an area in which the common power line CPL is disposed. For example, the second routing line RL2 may be electrically connected to the common power line CPL in a contact area in the first non-display area NA1 and/or the second non-display area NA2, but is not limited thereto. For example, the second routing line RL2 may be electrically connected to the common power line CPL in the entire area in which the common power line CPL is disposed.

The second routing line RL2 may be electrically connected to the common power line CPL in the non-display area NA of the substrate 100 to reduce a resistance or a line resistance value of the common power line CPL. Thus, it is possible to suppress an image quality defect, such as blurring, caused by a voltage change in the common power line CPL. Also, the second routing line RL2 may be disposed to overlap the common power line CPL in order to reduce a resistance of the common power line CPL without an increase in bezel width of the display apparatus 1000.

The second routing line RL2 included in the second routing part may be made of the same material and provided on the same layer as the plurality of touch electrodes TE1 and TE2 included in the touch electrode layer. For example, the second routing line RL2 may be formed by the same process as the plurality of touch electrodes TE1 and TE2. Accordingly, the second routing part may be formed together with the touch electrode layer without any additional process. However, the present disclosure is not limited thereto.

The manufacturing process of the touch sensor unit 140 may include a process of depositing a conductive material on the entire surface of the substrate 100, and a process of patterning the deposited conductive material into the plurality of first touch electrodes TE1 and the plurality of second touch electrodes TE2. In the patterning process of the manufacturing process of the touch sensor unit 140, the conductive material deposited in the non-display area NA of the substrate 100 overlapping the common power line CPL is not removed but left. Thus, the second routing line RL2 can be formed. Therefore, the conductive material which is not removed by the patterning process of the touch sensor unit 140 is used for the second routing line RL2 to reduce a resistance of the common power line CPL. Accordingly, the second routing line RL2 for reducing a resistance of the common power line CPL can be formed without any additional deposition process and patterning process.

Referring to FIG. 1, the display apparatus 1000 may further include a pad part PP, a gate driving circuit 200, an integrated circuit 400, and a flexible film 500.

The pad part PP may include a plurality of pads provided in the non-display area NA of the substrate 100. For example, the pad part PP may include a plurality of common power supply pads, a plurality of data input pads, a plurality of power supply pads, a plurality of control signal input pads, and a plurality of touch driving pads provided in the first non-display area NA1 of the substrate 100. However, this is just an example, and the present disclosure is not limited thereto.

The gate driving circuit 200 is disposed in the non-display area NA of the substrate 100 and may be electrically connected to a plurality of gate lines GL. The gate driving circuit 200 may generate gate signals based on gate control signals supplied from the integrated circuit 400 and output the generated gate signals sequentially through the plurality of gate lines GL. For example, the gate driving circuit 200 may include a shift register.

The gate driving circuit 200 may be disposed in the non-display area NA corresponding to at least one side of the display area AA. For example, two gate driving circuit 200 may be disposed in the third non-display area NA3 and the fourth non-display area NA4 of the substrate 100. The gate driving circuit 200 may be configured as an integrated circuit in the third non-display area NA3 and the fourth non-display area NA4 of the substrate 100 in the same process as a process of manufacturing the pixel array layer 120, e.g., a process of manufacturing the thin film transistor. However, this is just an example, and one gate driving circuit 200 may be disposed in the third non-display area NA3 or the fourth non-display area NA4 of the substrate 100.

Herein, the common power line CPL may be disposed to at least partially overlap the gate driving circuit 200. For example, the common power line CPL disposed in the third non-display area NA3 and the fourth non-display area NA4 may be disposed to overlap the gate driving circuit 200 from a plan view. Therefore, the size of the third non-display area NA3 and the fourth non-display area NA4 of the substrate 100 can be reduced or minimized. Thus, the bezel width of the display apparatus 1000 can be reduced or minimized compared to the case where the common power line CPL is disposed outside or inside the gate driving circuit 200.

Also, the first routing line RL1 and the second routing line RL2 may be disposed between the display area AA and a dam structure DM so as to overlap the gate driving circuit 200 in the third non-display area NA3 and the fourth non-display area NA4. Particularly, as described above, the second routing line RL2 is disposed to overlap the common power line CPL. Thus, at least a part of the second routing line RL2, e.g., the second routing line RL2 disposed to overlap the common power line CPL in the third non-display area NA3 and the fourth non-display area NA4, may be disposed to overlap the gate driving circuit 200. Therefore, an increase in bezel width according to the third non-display area NA3 and the fourth non-display area NA4 of the substrate 100, due to a disposition area of the plurality of first routing lines RL1 and the second routing line RL2, may be reduced or minimized.

The integrated circuit 400 may be mounted on the flexible film 500. The integrated circuit 400 may receive various powers, timing synchronization signals, and digital image data through the pad part PP and generate gate control signals based on the timing synchronization signals to control driving of the gate driving circuit 200. At the same time, the integrated circuit 400 may convert the digital image data into analog data signals (data voltages) and supply the analog data signals to the corresponding data lines DL.

The integrated circuit 400 may include a touch driving circuit. The integrated circuit 400 may supply a touch driving pulse to each of the plurality of second touch electrodes TE2 through the pad part PP and the first routing lines RL1 electrically connected to the second touch electrode TE2 among the plurality of first routing lines RL1. Also, the integrated circuit 400 may generate touch data by sensing changes in capacitance between the first touch electrode TE1 and the second touch electrode TE2 through the pad part PP and the first routing lines RL1 electrically connected to the first touch electrode TE1 among the plurality of first routing lines RL1. Then, the integrated circuit 400 may supply the generated touch data to a host circuit. The host circuit serves to calculate touch location information regarding a touch object based on the touch data supplied from the integrated circuit 400, and execute an application program associated with the calculated touch location information.

The flexible film 500 may be attached to the pad part PP. The flexible film 500 may serve to electrically connect a display driving circuit to the pad part PP, and electrically connect the pad part PP to the integrated circuit 400.

Referring to FIG. 1, the display apparatus 1000 may further include the dam structure DM.

The dam structure DM may be disposed in the non-display area NA of the substrate 100 so as to suppress the overflow of an encapsulation layer disposed on the pixel array layer 120. For example, the dam structure DM may be disposed in the non-display area NA, e.g., the first to fourth non-display areas NA1, NA2, NA3 and NA4, so as to enclose the entire display area AA.

Meanwhile, FIG. 1 illustrates that the dam structure DM is disposed in an outermost portion. However, the present disclosure is not limited thereto. For example, the dam structure DM may be disposed between the display area AA and the gate driving circuit 200.

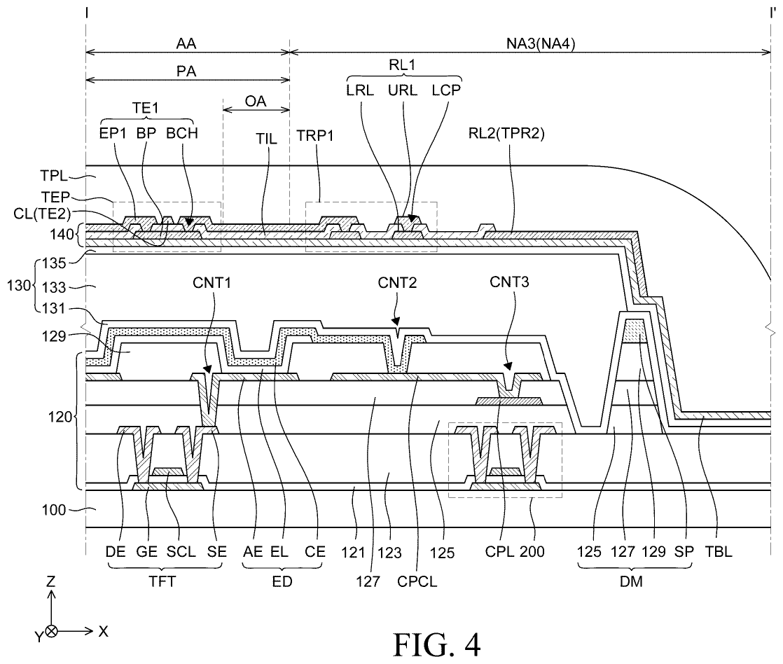

Hereinafter, a cross-sectional structure of the display apparatus 1000 according to an exemplary embodiment of the present disclosure will be described in more detail with reference to FIG. 4 through FIG. 6.

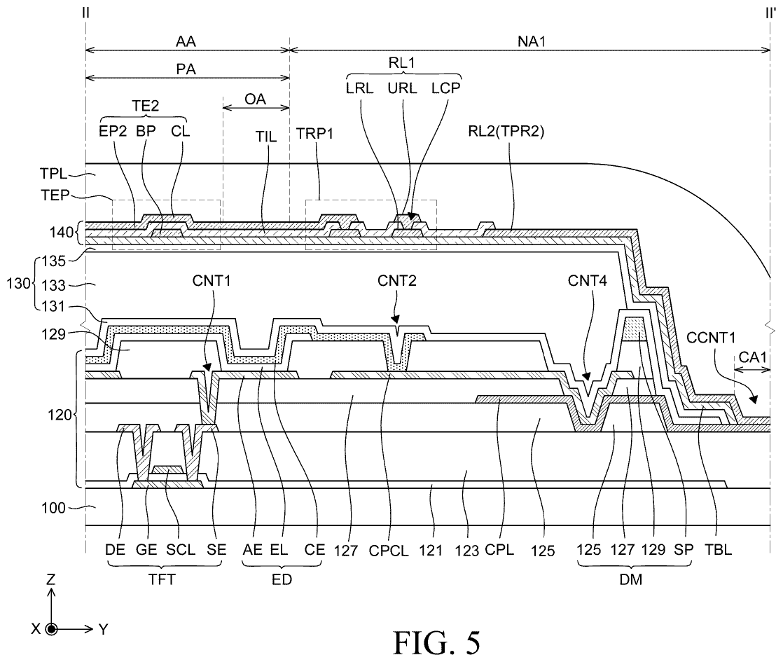

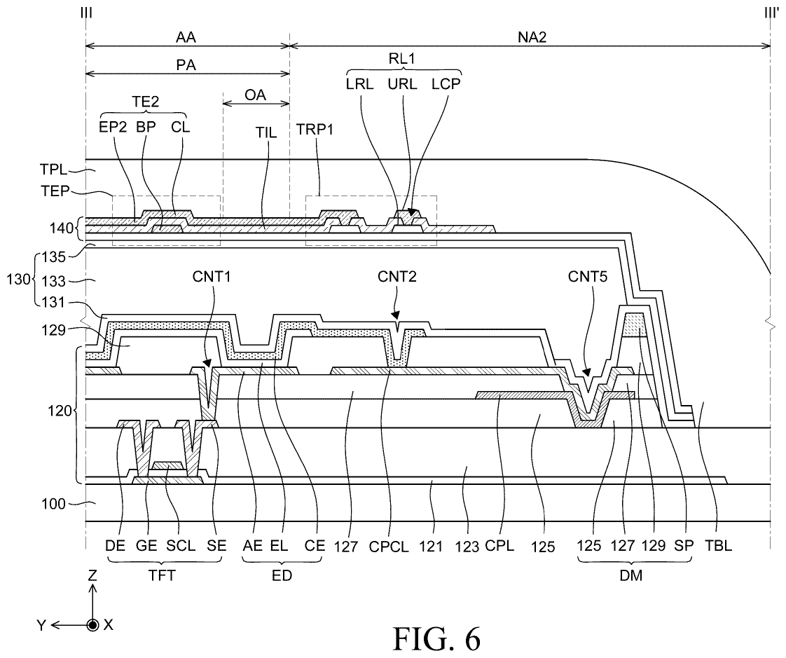

FIG. 4 is a cross-sectional view taken along the line I-I′ of FIG. 1. FIG. 5 is a cross-sectional view taken along the line II-II′ of FIG. 1. FIG. 6 is a cross-sectional view taken along the line III-III′ of FIG. 1.

First, a cross-sectional structure of the display area AA, the third non-display area NA3 and/or the fourth non-display area NA4 of the substrate 100 in the display apparats will be described with reference to FIG. 1 through FIG. 4. The display apparatus 1000 according to an exemplary embodiment of the present disclosure may include the substrate 100, the pixel array layer 120, an encapsulation layer 130, and the touch sensor unit 140. The display apparatus 1000 may further include the dam structure DM.

The substrate 100 is a base layer, and may be made of a plastic material or a glass material.

For example, the substrate 100 may be made of opaque or colored polyimide. For example, the substrate 100 made of polyimide may be prepared by curing polyimide resin which is coated to have a certain thickness on a front surface of a release layer disposed on a carrier substrate which is relatively thick. In this case, the carrier glass substrate may be separated from the substrate 100 by releasing the release layer through a laser releasing process. The display apparatus 1000 may further include a back plate coupled to a rear surface of the substrate 100 with respect to a thickness direction, e.g., a third direction Z, of the substrate 100. The back plate may maintain the substrate 100 in a plane state. For example, the back plate may contain polyethylene terephthalate. The back plate may be laminated on the rear surface of the substrate 100 separated from the carrier glass substrate.

For another example, the substrate 100 may be a flexible glass substrate. For example, the glass substrate 100 may be a thin glass substrate having a thickness of 100 micrometers or less. Alternatively, the glass substrate 100 may be a carrier glass substrate which has been etched to have a thickness of 100 micrometers or less through a substrate etching process.

The substrate 100 may include the display area AA and the non-display area NA enclosing the display area AA.

A buffer film may be provided on one surface of the substrate 100. The buffer layer may be provided on one surface of the substrate 100 to suppress the permeation of moisture into the pixel array layer 120 through the substrate vulnerable to moisture permeation. For example, the buffer film may be composed of a plurality of inorganic films which are alternately laminated. For example, the buffer film may be a multi-layered film in which one or more inorganic films of a silicon oxide film (SiOx), a silicon nitride film (SiNx), and a silicon oxynitride film (SiON) are alternately laminated. However, the present disclosure is not limited thereto. The buffer film may be omitted if necessary.

The pixel array layer 120 may be disposed on the substrate 100. The pixel array layer 120 may include a thin film transistor TFT, a gate insulating layer 121, an interlayer insulating layer 123, a first planarization layer 125, a second planarization layer 127, a bank pattern 129, and the LED ED.

The thin film transistor TFT may be disposed in a pixel area PA defined in the display area AA of the substrate 100. Meanwhile, the thin film transistor TFT shown in FIG. 4 may be the driving transistor DT electrically connected to the LED ED.

The thin film transistor TFT may include a semiconductor layer SCL, a gate electrode GE, a source electrode SE and a drain electrode DE disposed on the substrate 100 or the buffer film. FIG. 4 illustrates that the thin film transistor TFT has a top gate structure in which the gate electrode GE is disposed on the semiconductor layer SCL. However, the present disclosure is not limited thereto. The thin film transistor TFT may have a bottom gate structure in which the gate electrode GE is disposed under the semiconductor layer SCL. Alternatively, the thin film transistor TFT may have a double gate structure in which the gate electrode GE is disposed on and under the semiconductor layer SCL.

The semiconductor layer SCL may be provided on the substrate 100 or the buffer film. The semiconductor layer SCL may contain a silicon-based semiconductor material, an oxide-based semiconductor material or an organic-based semiconductor material. Also, the semiconductor layer SCL may have a single-layered structure or a multi-layered structure. A light shielding layer for blocking external light which is incident into the semiconductor layer SCL may be further provided between the buffer film and the semiconductor layer SCL.

The gate insulating layer 121 may be provided on the entire substrate 100 so as to cover the semiconductor layer SCL. The gate insulating layer 121 may include an inorganic layer, such as a silicon oxide film (SiOx), a silicon nitride film (SiNx) or a multi-layered film thereof. However, the material of the gate insulating layer 121 is not limited thereto.

The gate electrode GE may be provided on the gate insulating layer 121 so as to overlap the semiconductor layer SCL. For example, the gate electrode GE may be configured by a single layer made of molybdenum (MO), aluminum (Al), chrome (Cr), gold (Au), titanium (Ti), nickel (Ni), neodymium (Nd), copper (Cu) or an alloy thereof, or a multi-layer thereof. However, the material of the gate electrode GE is not limited thereto. In some exemplary embodiments, the gate electrode GE may be prepared together with the gate line GL.

The interlayer insulating layer 123 may be provided on the entire substrate 100 so as to cover the gate electrode GE and the gate insulating layer 121. The interlayer insulating layer 123 may provide a flat surface on the gate electrode GE and the gate insulating layer 121. However, the present disclosure is not limited thereto. The interlayer insulating layer 123 may be conformally formed to have a constant thickness on upper surfaces of the components disposed thereunder.

The source electrode SE and the drain electrode DE may be disposed on the interlayer insulating layer 123 so as to overlap the semiconductor layer SCL with the gate electrode GE interposed therebetween. In some exemplary embodiments, the source electrode SE and the drain electrode DE may be prepared together with the data line DL. For example, the source electrode SE, the drain electrode DE, and the data line DL may be simultaneously prepared through a process of patterning a source-drain electrode material.

The source electrode SE and the drain electrode DE may be connected to the semiconductor layer SCL through contact holes penetrating through the interlayer insulating layer 123 and the gate insulating layer 121, respectively. For example, the source electrode SE may be connected to a source region of the semiconductor layer SCL through the contact hole penetrating through the interlayer insulating layer 123 and the gate insulating layer 121. Also, the drain electrode DE may be connected to a drain region of the semiconductor layer SCL through the contact hole penetrating through the interlayer insulating layer 123 and the gate insulating layer 121.

Each of the source electrode SE and the drain electrode DE may be configured by a single layer made of molybdenum (MO), aluminum (Al), chrome (Cr), gold (Au), titanium (Ti), nickel (Ni), neodymium (Nd), copper (Cu) or an alloy thereof, or a multi-layer thereof. However, the present disclosure is not limited thereto.

The thin film transistor TFT provided in the pixel area PA of the substrate 100 as described above may constitute the pixel circuit PC of the pixel PX.

Also, the gate driving circuit 200 may be disposed in a gate driving circuit area defined in each of the third non-display area NA3 and the fourth non-display area NA4 of the substrate 100. The gate driving circuit 200 may include at least one transistor. For example, the gate driving circuit 200 may include at least one transistor having a substantially identical or similar structure to that of the thin film transistor TFT disposed in the pixel area PA. However, the present disclosure is not limited thereto.

The first planarization layer 125 may be disposed on the interlayer insulating layer 123. For example, the first planarization layer 125 may be disposed on the interlayer insulating layer 123 so as to cover the thin film transistor TFT and the gate driving circuit 200. The first planarization layer 125 may provide a flat surface on the thin film transistor TFT and the gate driving circuit 200.

For example, the first planarization layer 125 may be configured as an organic film made of acryl resin, epoxy resin, phenolic resin, polyamide resin or polyimide resin. However, the material of the first planarization layer 125 is not limited thereto.

The common power line CPL may be disposed on the first planarization layer 125. For example, the common power line CPL may be disposed on the first planarization layer 125 in each of the third non-display area NA3 and the fourth non-display area NA4. For example, the common power line CPL may be disposed to overlap the gate driving circuit 200 disposed in each of the third non-display area NA3 and the fourth non-display area NA4.

The common power line CPL may contain the same material as the source electrode SE and the drain electrode DE of the thin film transistor TFT. For example, the common power line CPL may be configured by a single layer made of molybdenum (MO), aluminum (Al), chrome (Cr), gold (Au), titanium (Ti), nickel (Ni), neodymium (Nd), copper (Cu) or an alloy thereof, or a multi-layer thereof. However, the present disclosure is not limited thereto.

The second planarization layer 127 may be disposed on the first planarization layer 125. For example, the second planarization layer 127 may be disposed on the first planarization layer 125 so as to cover the common power line CPL. The second planarization layer 127 may provide a flat surface on the common power line CPL. The second planarization layer 127 may be made of the same material as the first planarization layer 125, but is not limited thereto.

Meanwhile, FIG. 4 illustrates that the common power line CPL is disposed on the first planarization layer 125. However, the present disclosure is not limited thereto. For example, the common power line CPL may be simultaneously provided on the interlayer insulating layer 123 through the same process as the source electrode SE and the drain electrode DE of the thin film transistor TFT. In this case, the second planarization layer 127 may be omitted.

The bank pattern 129 may be disposed on the second planarization layer 127. The bank pattern 129 is disposed on the second planarization layer 127 to define an opening area OA inside the pixel area PA of the display area AA. Meanwhile, in the present disclosure, the bank pattern 129 may also be defined as a pixel define film, and the opening area OA may also be defined as an emission area. In the present disclosure, the bank pattern 129 may also be defined as a bank layer.

The LED ED is disposed on the thin film transistor TFT, and may include a first electrode AE, an emission layer EL, and a second electrode CE. Meanwhile, in the present disclosure, the first electrode AE may also be defined as an anode or a pixel driving electrode, and the second electrode CE may also be defined as a cathode or a common electrode.

The first electrode AE may be disposed on the second planarization layer 127. For example, a part of the first electrode AE may be disposed on the second planarization layer 127 so as to overlap at least a part of the opening area OA of the pixel area PA. Also, the other part of the first electrode AE may be disposed on the second planarization layer 127 so as to overlap at least a part of an area except the opening area OA of the pixel area PA.

The first electrode AE may be connected to the source electrode SE of the thin film transistor TFT through a first contact hole CNT1 penetrating through the second planarization layer 127 and the first planarization layer 125. In this case, an edge portion except the part of the first electrode AE overlapping the opening area OA of the pixel area PA may be covered by the bank pattern 129. The bank pattern 129 may cover the edge portion of the first electrode AE to define the opening area OA of the pixel area PA.

The first electrode AE may contain a metal material having a high reflectivity. For example, the first electrode AE may have a multi-layered structure such as a laminated structure (Ti/Al/Ti) of aluminum (Al) and titanium (Ti), a laminated structure (ITO/Al/ITO) of aluminum (Al) and indium tin oxide (ITO), an APC (Ag/Pd/Cu) alloy, and a laminated structure (ITO/APC/ITO) of an APC alloy and ITO. Alternatively, the first electrode AE may have a single-layered structure including one or an alloy of two or more selected from silver (Ag), aluminum (Al), molybdenum (Mo), gold (Au), magnesium (Mg), calcium (Ca), and barium (Ba). However, the present disclosure is not limited thereto.

The emission layer EL may be provided on the entire display area AA of the substrate 100 so as to cover the first electrode AE and the bank pattern 129. The emission layer EL may include two or more emission parts for emitting white light.

For example, the emission layer EL may include a first emission part and a second emission part for emitting white light by combining first light and second light. Herein, the first emission part may be configured to emit the first light, and may include one of a blue emission part, a green emission part, a red emission part, a yellow emission part, and a yellow-green emission part. The second emission part may include an emission part configured to emit the second light having a complementary color relationship with the first light among the blue emission part, the green emission part, the red emission part, the yellow emission part, and the yellow-green emission part.

For another example, the emission layer EL may include one of a blue emission part, a green emission part, and a red emission part for emitting light of a color corresponding to a color set for the pixel PX. For example, the emission layer EL may include one of an organic emission layer, an inorganic emission layer, and a quantum-dot emission layer. The emission layer EL may have a laminated or mixed structure of an organic emission layer or an inorganic emission layer and a quantum-dot emission layer.

However, the emission part included in the emission layer EL is not limited thereto. The emission part may be configured in various forms.

In addition, the LED ED may further include a functional layer for enhancing the emission efficiency and/or lifetime of the emission layer EL.

The second electrode CE may be disposed on the emission layer EL. The second electrode CE may be electrically connected to the emission layer EL. For example, the second electrode CE may be provided in the entire display area AA of the substrate 100 so as to be commonly connected to the emission layers EL provided in the respective pixel areas PA.

The second electrode CE may contain a transparent conductive material or a semi-transmissive conductive material which can transmit light. When the second electrode CE is made of a semi-transmissive conductive material, the emission efficiency of light emitted from the LED ED may be enhanced by a micro-cavity. For example, the semi-transmissive conductive material may include magnesium (Mg), silver (Ag) or an alloy of magnesium (Mg) and silver (Ag).

In addition, a capping layer configured to adjust a refractive index of light emitted from the LED ED and enhance the emission efficiency of light may be further provided on the second electrode CE.

Also, a common power connection line CPCL may be disposed on the second planarization layer 127. For example, the common power connection line CPCL may be disposed in the third non-display area NA3 and the fourth non-display area NA4.

The common power connection line CPCL may be disposed on the same layer as the first electrode AE. For example, the first electrode AE may be simultaneously made of the same material as the common power connection line CPCL.

The common power connection line CPCL may be disposed to overlap at least a part of the gate driving circuit 200 and the common power line CPL. For example, the common power connection line CPCL may be disposed in the third non-display area NA3 and the fourth non-display area NA4 so as to overlap the gate driving circuit 200 and the common power line CPL. Also, the common power connection line CPCL may be electrically connected to the common power line CPL.

An edge portion of the second electrode CE disposed in each of the third non-display area NA3 and the fourth non-display area NA4 of the substrate 100 may be electrically connected to the common power connection line CPCL through a second contact hole CNT2 penetrating through the bank pattern 129.

Referring to FIG. 5 and FIG. 6, an edge portion of the second electrode CE disposed in each of the first non-display area NA1 and the second non-display area NA2 of the substrate 100 may also be electrically connected to the common power connection line CPCL through the second contact hole CNT2 penetrating through the bank pattern 129.

Referring back to FIG. 4, the common power connection line CPCL in the third non-display area NA3 and the fourth non-display area NA4 may be electrically connected to the common power line CPL through a third contact hole CNT3 penetrating through the second planarization layer 127.

Thus, the second electrode CE is electrically connected to the common power line CPL through the common power connection line CPCL. Therefore, the pad part PP may receive a constant common power voltage, e.g., the second power voltage VSS, through the common power line CPL and the common power connection line CPCL.

Herein, the common power line CPL for supplying the constant common power voltage, e.g., the second power voltage VSS, to the second electrode CE is disposed to overlap at least a part of the gate driving circuit 200 in the third non-display area NA3 and the fourth non-display area NA4. Therefore, the size of the third non-display area NA3 and the fourth non-display area NA4 of the substrate 100 can be reduced or minimized. Accordingly, the bezel width of the display apparatus 1000 can be reduced or minimized.

Meanwhile, referring to FIG. 5, the common power connection line CPCL disposed in the first non-display area NA1 of the substrate 100 may extend from an outer portion of the display area AA so as to cover the dam structure DM, e.g., side surfaces of first and second layers of the dam structure DM and an upper surface of the second layer. Also, the common power connection line CPCL may be electrically connected to the common power line CPL through a fourth contact hole CNT4 penetrating through the second planarization layer 127. Referring to FIG. 6, the common power connection line CPCL disposed in the second non-display area NA2 of the substrate 100 may extend from an outer portion of the display area AA so as to cover the dam structure DM, e.g., the side surfaces of the first and second layers of the dam structure DM and the upper surface of the second layer. Also, the common power connection line CPCL may be electrically connected to the common power line CPL through a fifth contact hole CNT5 penetrating through the second planarization layer 127.

The encapsulation layer 130 may be provided to enclose the pixel array layer 120. The encapsulation layer 130 may serve to suppress the permeation of oxygen or moisture into the LED ED.

The encapsulation layer 130 may include a first inorganic encapsulation layer 131, an organic encapsulation layer 133 on the first inorganic encapsulation layer 131, and a second inorganic encapsulation layer 135 on the organic encapsulation layer 133.

The first inorganic encapsulation layer 131 and the second inorganic encapsulation layer 135 may serve to suppress the permeation of moisture or oxygen. For example, each of the first inorganic encapsulation layer 131 and the second inorganic encapsulation layer 135 may contain an inorganic material such as silicon nitride, aluminum nitride, zirconium nitride, titanium nitride, hafnium nitride, tantalum nitride, silicon oxide, aluminum oxide, or titanium oxide. The first inorganic encapsulation layer 131 and the second inorganic encapsulation layer 135 may be prepared through a chemical vapor deposition process or an atomic layer deposition process.

The organic encapsulation layer 133 may be disposed between the first inorganic encapsulation layer 131 and the second inorganic encapsulation layer 135. The organic encapsulation layer 133 may be formed to have a greater thickness than the first inorganic encapsulation layer 131 and/or the second inorganic encapsulation layer 135. Thus, the organic encapsulation layer 133 can cover particles which may be generated in the manufacturing process. The organic encapsulation layer 133 may contain an organic material such as silicon oxycarbon (SiOCx) acryl or an epoxy-based resin. The organic encapsulation layer 133 may be prepared through a coating process, e.g., an ink-jet coating process or a slit coating process.

The dam structure DM may be disposed in the non-display area NA of the substrate 100 so as to suppress the overflow of the organic encapsulation layer 133. For example, the dam structure DM may be disposed outside gate driving circuit 200 and the common power line CPL disposed in the non-display area NA so as to enclose the display area AA.

The dam structure DM may have a quadruple-layered structure vertically laminated on the substrate 100. For example, the dam structure DM may include a first layer made of the same material as the first planarization layer 125 and a second layer made of the same material as the second planarization layer 127. Also, the dam structure DM may include a third layer made of the same material as the bank pattern 129 and a fourth layer configured as a spacer SP.

The first layer may have a trapezoidal sectional structure laminated on the interlayer insulating layer 123. The second layer may have a trapezoidal sectional structure laminated on the second layer. The third layer may have a trapezoidal sectional structure laminated on the second layer. The fourth layer may have a trapezoidal sectional structure laminated on the third layer. Meanwhile, in some exemplary embodiments, when the thickness of the organic encapsulation layer 133 is small enough to easily control the diffusibility of the organic encapsulation layer 133, the dam structure DM may be formed to have a relatively small height. For example, in this case, the fourth layer may be omitted.

The dam structure DM may be entirely covered by the first inorganic encapsulation layer 131 and/or the second inorganic encapsulation layer 135. The organic encapsulation layer 133 may be in contact with a part of an inner wall surface and a part of an upper wall surface of the dam structure DM. However, the present disclosure is not limited thereto. The organic encapsulation layer 133 may be provided to be in contact with only a part of the inner wall surface of the dam structure DM.

The touch sensor unit 140 is disposed on the encapsulation layer 130, and may include a touch buffer layer TBL, a touch electrode part TEP, a first routing part TRP1, a second routing part TRP2, and a touch protection layer TPL.

The touch buffer layer TBL may be disposed to cover the encapsulation layer 130. The touch buffer layer TBL may provide a flat surface on the encapsulation layer 130. For example, as shown in FIG. 4, the touch buffer layer TBL may be entirely disposed in the display area AA, the third non-display area NA3, and the fourth non-display area NA4 so as to cover the encapsulation layer 130.

The touch buffer layer TBL may be made of an inorganic material or an organic material. The touch buffer layer TBL may be prepared through a chemical vapor deposition process.

The touch electrode part TEP is disposed on the touch buffer layer TBL in the display area AA, and may include a plurality of touch electrodes TE.

The touch electrode part TEP will be described in more detail with reference to FIG. 5 and FIG. 6 as well as FIG. 4. The touch electrode part TEP may include a first touch electrode layer, a touch insulating layer TIL, and a second touch electrode layer.

The first touch electrode layer may include the plurality of bridge patterns BP disposed on the touch buffer layer TBL. Each of the plurality of bridge patterns BP may be disposed on the touch buffer layer TBL so as to overlap the bank pattern 129 disposed in the display area AA.

The touch insulating layer TIL may be disposed on the touch buffer layer TBL so as to enclose the plurality of bridge patterns BP. Herein, as shown in FIG. 4, the touch insulating layer TIL may include a bridge contact hole BCH for exposing one side and the other side of each of the plurality of bridge patterns BP.

The touch insulating layer TIL may contain an inorganic material, such as silicon oxide (SiOx) or silicon nitride (SiNx). However, the material of the touch insulating layer TIL is not limited thereto.

The second touch electrode layer may include the plurality of first electrode patterns EP1 and the plurality of second touch electrodes TE2.

The plurality of first electrode patterns EP1 may be disposed on the touch insulating layer TIL so as to be spaced apart from each other in the first direction X and the second direction Y. In this case, as shown in FIG. 4, two first electrode patterns EP1 adjacent to each other in the first direction X may be electrically connected to the bridge pattern BP through the bridge contact holes BCH. Accordingly, the plurality of first electrode patterns EP1 disposed in the first direction X are electrically connected to the plurality of bridge patterns BP so as to form one first touch electrode TE1.

The plurality of second touch electrodes TE2 may extend along the second direction Y and may be disposed on the touch insulating layer TIL so as to be spaced apart from each other in the first direction X. Thus, the plurality of second touch electrodes TE2 may be electrically insulated from the plurality of first touch electrodes TE1. For example, as shown in FIG. 5 and FIG. 6, each of the plurality of second touch electrodes TE2 may include the plurality of second electrode patterns EP2 disposed on the touch insulating layer TIL so as to be spaced apart from each other in the second direction Y. Also, each of the plurality of second touch electrodes TE2 may include the plurality of connection lines CL disposed between two second electrode patterns EP2 adjacent to each other in the second direction Y and electrically connecting the two second electrode patterns EP2. Therefore, the plurality of second electrode patterns EP2 disposed in the second direction Y are electrically connected to the plurality of connection lines CL so as to form one second touch electrode TE2.

Referring to FIG. 1 and FIG. 4 through FIG. 6, the first routing part TRP1 may be disposed in the non-display area NA, e.g., the first to fourth non-display areas NA1, NA2, NA3 and NA4, so as to enclose the display area AA of the substrate 100. The first routing part TRP1 may include the plurality of first routing lines RL1 electrically connecting the touch electrode TE to the pad part PP.

Each of the plurality of first routing lines RL1 may be disposed on the touch insulating layer TIL in the first to fourth non-display areas NA1, NA2, NA3 and NA4.

As described above with reference to FIG. 1, each of the plurality of first routing lines RL1 may be electrically connected to the pad part PP.

Also, as shown in FIG. 4, some of the plurality of first routing lines RL1, e.g., the first routing lines RL1 disposed in the third non-display area NA3 and/or the fourth non-display area NA4, may be electrically connected to the plurality of first touch electrodes TE1, respectively. For example, the first routing lines RL1 disposed in the third non-display area NA3 and/or the fourth non-display area NA4 may extend from the third non-display area NA3 and/or the fourth non-display area NA4 to the display area AA in which the touch electrode part TEP is disposed. Thus, the first routing lines RL1 may be electrically connected to the corresponding first touch electrode TE1.

Further, as shown in FIG. 6, some of the plurality of first routing lines RL1, e.g., the first routing lines RL1 disposed in the second non-display area NA2, may be electrically connected to the plurality of second touch electrodes TE2, respectively. For example, the first routing lines RL1 disposed in the second non-display area NA2 may extend from the second non-display area NA2 to the display area AA in which the touch electrode part TEP is disposed. Thus, the first routing lines RL1 may be electrically connected to the corresponding second touch electrode TE2.

Referring to FIG. 4 through FIG. 6, each of the plurality of first routing lines RL1 may include a lower touch routing line LRL and an upper touch routing line URL.

The lower touch routing line LRL is disposed on the touch buffer layer TBL, and may be made of the same conductive material as the bridge pattern BP. The lower touch routing line LRL may be made of the same material and provided on the same layer as the bridge pattern BP. For example, the lower touch routing line LRL may be simultaneously made of the same conductive material as the bridge pattern BP.

The upper touch routing line URL may be disposed on the touch insulating layer TIL so as to overlap the lower touch routing line LRL. Also, the upper touch routing line URL may be electrically connected to the lower touch routing line LRL through a line contact portion LCP penetrating through the touch insulating layer TIL. The upper touch routing line URL may be made of the same conductive material as the electrode patterns EP1 and EP2 of the touch electrode TE. The upper touch routing line URL may be made of the same material and provided on the same layer as the electrode patterns EP1 and EP2 of the touch electrode TE. For example, the upper touch routing line URL may be simultaneously made of the same conductive material as the electrode patterns EP1 and EP2 of the touch electrode TE.

The line contact portion LCP may include a slit having a line shape or a dotted line shape. Therefore, the upper touch routing line URL may be electrically connected to the lower touch routing line LRL through the line contact portion LCP. Thus, a resistance of the upper touch routing line URL can be reduced by the lower touch routing line LRL.

Referring to FIG. 1 and FIG. 4 through FIG. 6, the second routing part TRP2 may be disposed in the non-display area NA, e.g., the first to fourth non-display areas NA1, NA2, NA3 and NA4, so as to enclose the display area AA of the substrate 100. The second routing part TRP2 may include the second routing line RL2.

Referring to FIG. 4, a part of the second routing line RL2, e.g., the second routing line RL2 disposed in the third non-display area NA3 and the fourth non-display area NA4, may overlap the gate driving circuit 200 and the common power line CPL. The second routing line RL2 may be disposed outside the first routing part TRP1 of the non-display area NA so as to overlap the gate driving circuit 200 and the common power line CPL.

The second routing line RL2 of the second routing part TRP2 may be made of the same conductive material as the touch electrode TE and/or the first routing line RL1. The second routing line RL2 may be made of the same material and provided on the same layer as the touch electrode TE and/or the first routing line RL1. For example, the second routing line RL2 may be simultaneously made of the same conductive material as the touch electrode TE and/or the first routing line RL1.

For example, the second routing line RL2 may have a single-layered structure simultaneously made of the same material as one of the bridge pattern BP, the electrode patterns EP1 and EP2, the lower touch routing line LRL, and the upper touch routing line URL. However, the structure of the second routing line RL2 is not limited thereto. Like the first routing line RL1, the second routing line RL2 may have a double-layered structure including a lower routing line and an upper routing line.

The second routing line RL2 is electrically connected to the common power line CPL in at least a part of the non-display area NA. Thus, a resistance of the common power line CPL can be reduced.

For example, referring to FIG. 1 and FIG. 5, the second routing line RL2 may be disposed in the first non-display area NA1 so as to overlap the common power line CPL. The second routing line RL2 may extend to a first contact area CA1 in the first non-display area NA1 of the substrate 100. Thus, the second routing line RL2 in the first contact area CA1 may be electrically connected to the common power line CPL through a first common contact hole CCNT1 penetrating through the touch buffer layer TBL and the encapsulation layer 130.

More specifically, as shown in FIG. 5, the common power line CPL may extend from the first non-display area NA1 to the first contact area CA1 in the first non-display area NA1 of the substrate 100 through the dam structure DM, e.g., the upper and side surfaces of the first layer of the dam structure DM. The first contact area CA1 may be located outside the dam structure DM in the first non-display area NA1. Herein, the second routing line RL2 may be electrically connected to the common power line CPL through the first common contact hole CCNT1, which exposes at least a part of the common power line CPL, in the first contact area CA1 of the first non-display area NA1.

Therefore, the second routing line RL2 is electrically connected to the common power line CPL in the first non-display area NA1, e.g., the first contact area CA1, corresponding to an upper edge area of the display apparatus 1000. Thus, a resistance of the common power line CPL can be reduced.

As described above, the second routing line RL2 may be disposed in the non-display area NA so as to overlap the gate driving circuit 200 and the common power line CPL. Also, the second routing line RL2 may be electrically connected to the common power line CPL in at least a part of the non-display area NA, e.g., the first non-display area NA1. Thus, a resistance of the common power line CPL can be reduced without an increase in bezel width of the display apparatus 1000.

Referring to FIG. 4 through FIG. 6, the touch protection layer TPL may be disposed to cover the components, e.g., the touch electrode part TEP, the first routing part TRP1, and the second routing part TRP2, included in the touch sensor unit 140. The touch protection layer TPL may be made of an organic material and may serve to planarize an upper portion of the touch sensor unit 140, but is not limited thereto.

As described above, in the display apparatus 1000 according to an exemplary embodiment of the present disclosure, a resistance of the common power line CPL can be reduced by the second routing part TRP2, e.g., the second routing line RL2 disposed in the non-display area NA of the substrate 100. Thus, it is possible to suppress an image quality defect, such as blurring, caused by a voltage change in the common power line CPL.

Also, in the display apparatus 1000 according to an exemplary embodiment of the present disclosure, the second routing line RL2 is disposed in the non-display area NA so as to overlap the common power line CPL. Thus, a resistance of the common power line CPL can be reduced without an increase in width of the common power line CPL or an increase in bezel width.

Further, in the display apparatus 1000 according to an exemplary embodiment of the present disclosure, the common power line CPL is disposed in the non-display area NA, e.g., the third non-display area NA3 and the fourth non-display area NA4 corresponding to left and right edges of the display apparatus 1000, so as to overlap the gate driving circuit 200. Thus, the size of the third non-display area NA3 and the fourth non-display area NA4 of the substrate 100 can be reduced or minimized. Therefore, the bezel width of the display apparatus 1000 can be reduced or minimized.

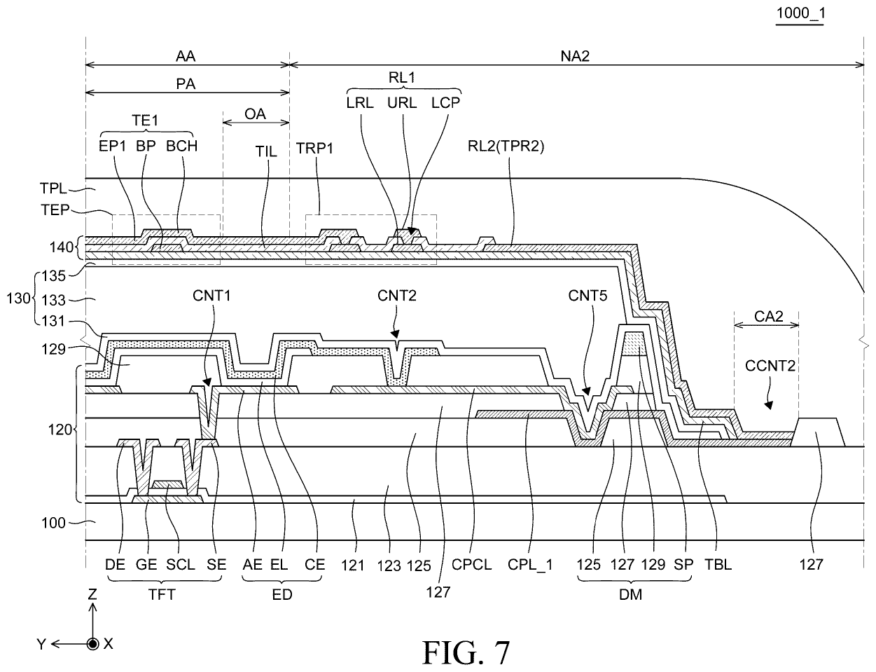

FIG. 7 is a cross-sectional view of a display apparatus according to another exemplary embodiment of the present disclosure.

FIG. 7 illustrates a modification example of a cross-sectional structure of a display apparatus 1000_1 in the display area AA and the second non-display area NA2 of the substrate 100 described above with reference to FIG. 6. Therefore, repeated description will be omitted for the convenience of description.

Referring to FIG. 7, the second routing line RL2 may be electrically connected to a common power line CPL_1 in at least a part of the non-display area NA, e.g., the second non-display area NA2.

For example, referring to FIG. 7, the second routing line RL2 may be disposed in the second non-display area NA2 so as to overlap the common power line CPL_1. Also, the second routing line RL2 may extend to a second contact area CA2 in the second non-display area NA2 of the substrate 100. Thus, the second routing line RL2 in the second contact area CA2 may be electrically connected to the common power line CPL_1 through a second common contact hole CCNT2 penetrating through the touch buffer layer TBL and the encapsulation layer 130.

More specifically, as shown in FIG. 7, the common power line CPL_1 may extend from the second non-display area NA2 to the second contact area CA2 in the second non-display area NA2 of the substrate 100 through the dam structure DM, e.g., the upper and side surfaces of the first layer of the dam structure DM. The second contact area CA2 may be located outside the dam structure DM in the second non-display area NA2. Herein, the second routing line RL2 may be electrically connected to the common power line CPL_1 through the second common contact hole CCNT2, which exposes at least a part of the common power line CPL_1, in the second contact area CA2 of the second non-display area NA2.

Therefore, the second routing line RL2 is electrically connected to the common power line CPL_1 in the second non-display area NA2, e.g., the second contact area CA2, corresponding to a lower edge area of the display apparatus 1000_1 described above with reference to FIG. 7 as well as in the first non-display area NA1 corresponding to the upper edge area of the display apparatus 1000 described above with reference to FIG. 5. Thus, a resistance of the common power line CPL_1 can be further reduced.

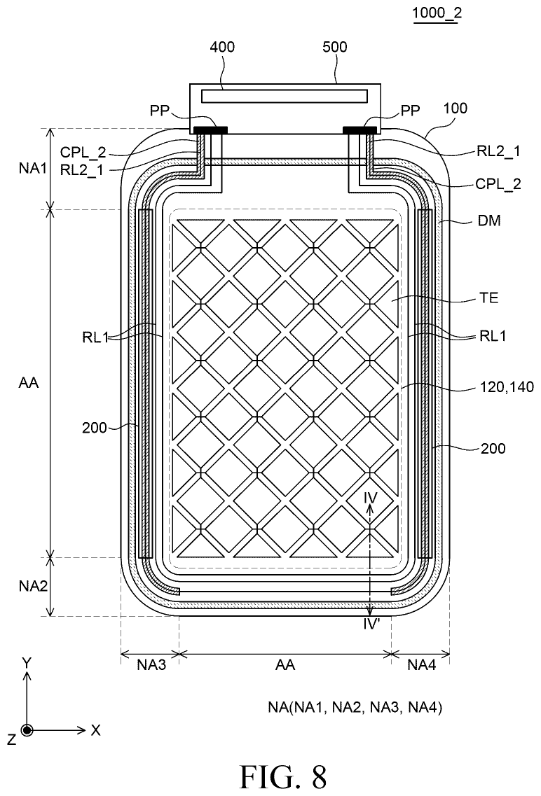

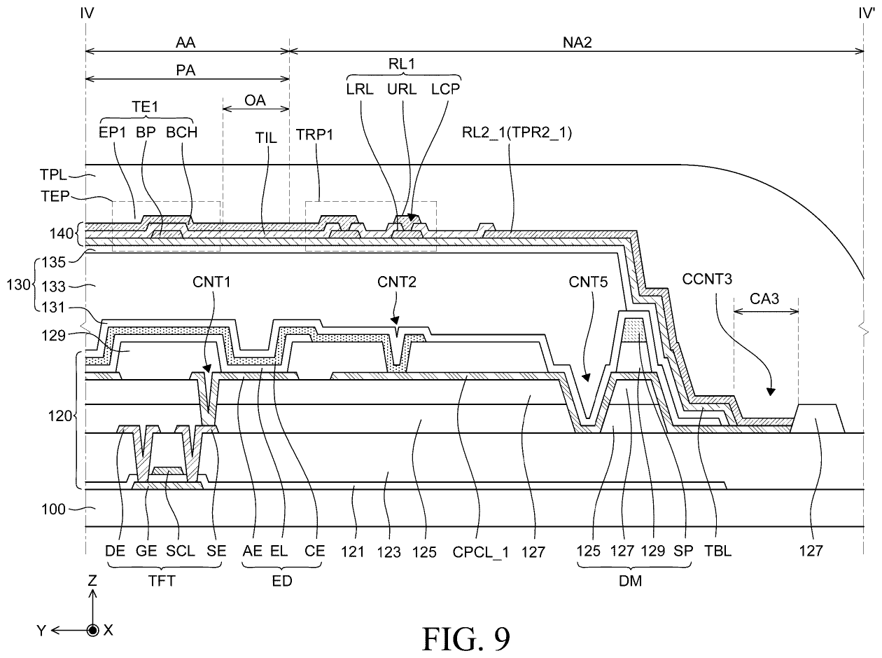

FIG. 8 is a plan view of a display apparatus according to yet another exemplary embodiment of the present disclosure. FIG. 9 is a cross-sectional view taken along the line IV-IV′ of FIG. 8.

FIG. 8 and FIG. 9 illustrates a modification example of FIG. 1 through FIG. 6 regarding the connection relationship between a common power line CPL_2 and a second routing line RL2_1. Therefore, repeated description will be omitted for the convenience of description.

Referring to FIG. 8, a display apparatus 1000_2 according to yet another exemplary embodiment of the present disclosure may include the substrate 100, the pixel array layer 120, the touch sensor unit 140, and the common power line CPL_2.

The common power line CPL_2 may have a constant line width and may be disposed to enclose at least a part of the display area AA of the substrate 100. For example, the common power line CPL_2 may be disposed in at least a part of the first non-display area NA1 and in the third and fourth non-display areas NA3 and NA4 so as to enclose at least a part of the display area AA. For example, two common power lines CPL_2 may be disposed on both sides of the display area AA of the substrate 100. One end of one of the two common power lines CPL_2 may be disposed on one side of the first non-display area NA1, and the other end may be disposed in the third non-display area NA3. Also, one end of the other of the two common power lines CPL_2 may be disposed on one side of the first non-display area NA1, and the other end may be disposed in the fourth non-display area NA4. Therefore, the common power line CPL_2 may have a shape, at least a part of which is opened, in a plan view and may be disposed in the first non-display area NA1 and the second non-display area NA2, but is not limited thereto.

The second routing line RL2_1 may be disposed to overlap the common power line CPL_2. Also, the second routing line RL2_1 may be electrically connected to the common power line CPL_2 in a contact area which is a part of an area in which the common power line CPL_2 is disposed. For example, the second routing line RL2_1 may be disposed in the first, third and fourth non-display areas NA1, NA3 and NA4 so as to overlap the common power line CPL_2. Also, as described above with reference to FIG. 1 through FIG. 6, the second routing line RL2_1 may be electrically connected to the common power line CPL_2 in the first non-display area NA1.

Also, the second routing line RL2_1 may be electrically connected to the pad part PP to receive a common power voltage, e.g., the second power voltage VSS. Herein, in the second non-display area NA2, the second routing line RL2_1 may be electrically connected to a common power connection line CPCL_1 electrically connected to the second electrode CE of the LED ED. Therefore, the second electrode CE of the LED ED disposed in the display area AA is electrically connected to the second routing line RL2_1 through the common power connection line CPCL_1. Thus, the second routing line RL2_1 may receive a common power voltage, e.g., the second power voltage VSS, through the pad part PP, the second routing line RL2_1, and the common power connection line CPCL_1.

This will be described in more detail with reference to FIG. 9. The common power line CPL_2 is not disposed in the second non-display area NA2, and the common power connection line CPCL_1 may be electrically connected directly to the second routing line RL2_1 of a second routing part TRP2_1.

For example, the common power connection line CPCL_1 disposed in the second non-display area NA2 of the substrate 100 may extend from the second non-display area NA2 to a third contact area CA3 in the second non-display area NA2 of the substrate 100 through the dam structure DM, e.g., the side surfaces of the first and second layers of the dam structure DM and the upper surface of the second layer. The third contact area CA3 may be located outside the dam structure DM in the second non-display area NA2. Herein, the second routing line RL2_1 may be electrically connected to the common power connection line CPCL_1 through the third common contact hole CCNT3, which exposes at least a part of the common power connection line CPCL_1, in the third contact area CA3 of the second non-display area NA2.

Therefore, the second routing line RL2_1 is electrically connected to the common power connection line CPCL_1 in the second non-display area NA2, e.g., the third contact area CA3, corresponding to a lower edge area of the display apparatus 1000_2. Accordingly, the second electrode CE of the LED ED may receive a constant common power voltage, e.g., the second power voltage VSS, through the pad part PP, the second routing line RL2_1, and the common power connection line CPCL_1.

Herein, the second routing line RL2_1 is connected directly to the common power connection line CPCL_1 connected to the second electrode CE without disposing the common power line CPL_1 in the second non-display area NA2 to supply the common power voltage, e.g., the second power voltage VSS. Therefore, the bezel width of the display apparatus 1000_2 corresponding to the second non-display area NA2 can be further reduced.

The exemplary embodiments of the present disclosure can also be described as follows:

According to an aspect of the present disclosure, there is provided a display apparatus. The display apparatus includes a substrate including a display area and a non-display area enclosing the display area, a pixel disposed in the display area of the substrate and including at least one transistor and a light emitting diode, a touch sensor unit disposed on the pixel and including at least one touch electrode, a common power line disposed in the non-display area of the substrate and connected to the light emitting diode and a gate driving circuit disposed in the non-display area of the substrate. The common power line and the gate driving circuit overlap each other in at least a part of the non-display area.

The non-display area may include a first non-display area disposed at a first edge of the substrate, a second non-display area disposed at a second edge of the substrate opposing the first non-display area, a third non-display area disposed at a third edge of the substrate and a fourth non-display area disposed at a fourth edge of the substrate opposing the third non-display area.

The gate driving circuit may be disposed in the third non-display area and the fourth non-display area, the common power line may be disposed in a part of the first non-display area and in the second to fourth non-display areas, and the gate driving circuit and the common power line overlap each other in at least one of the third non-display area and the fourth non-display area.

The touch sensor unit may include a touch electrode part including at least one touch electrode, a first routing part including a first routing line disposed in a part of the first non-display area and in the second to fourth non-display areas and a second routing part including a second routing line disposed in a part of the first non-display area and in the second to fourth non-display areas, and the second routing line overlaps the common power line.

The gate driving circuit and the second routing line may overlap each other in at least one of the third non-display area and the fourth non-display area.

The second routing line may be disposed outside the first routing line.

The display apparatus may further include a dam structure disposed in the first to fourth non-display areas and outside the gate driving circuit and the common power line.

The display apparatus may further include a pad part disposed in the first non-display area. The common power line may be electrically connected to the pad part to receive a common power voltage.

The gate driving circuit is disposed on the same layer as the at least one transistor.

The display apparatus may further include a planarization layer disposed on the at least one transistor, an interlayer insulating layer disposed on the planarization layer and a bank layer disposed on the interlayer insulating layer and defining a pixel area of the pixel and an opening area inside the pixel area. The light emitting diode may include a first electrode disposed on the interlayer insulating layer and connected to the at least one transistor through a first contact hole penetrating through the interlayer insulating layer and the planarization layer, an emission layer disposed on the first electrode and being in contact with the first electrode in the opening area and a second electrode disposed on the emission layer.

The display apparatus may further include a common power connection line disposed on the interlayer insulating layer in the non-display area. The second electrode may be in contact with the common power connection line through a second contact hole penetrating through the bank layer in the non-display area.

The common power connection line may be in contact with the common power line through a third contact hole penetrating through the interlayer insulating layer in the third non-display area and the fourth non-display area.

The display apparatus may further include an encapsulation layer extending to the non-display area while covering the pixel in the display area and a dam structure disposed in the non-display area.

The touch sensor unit may include a first touch electrode and a second touch electrode disposed on the encapsulation layer in the display area, a first routing line disposed on the encapsulation layer in the non-display area and a second routing line disposed on the encapsulation layer and outside the first routing line in the non-display area.

The second routing line may extend to a first contact area in the first non-display area, wherein in the first contact area, at least a part of the common power line is exposed, and the second routing line is in contact with the common power line in the first contact area. The first contact area may be disposed outside the dam structure.

The second routing line may extend to a second contact area in the second non-display area, wherein in the second contact area, at least a part of the common power line is exposed and the second routing line may be in contact with the common power line in the second contact area. The second contact area may be disposed outside the dam structure.

The gate driving circuit may be disposed in the third non-display area and the fourth non-display area. The common power line may be disposed in a part of the first non-display area and in the third and fourth non-display areas. The gate driving circuit and the common power line may overlap each other in at least one of the third non-display area and the fourth non-display area.

The second routing line may extend to a third contact area in the second non-display area, wherein in the third contact area, at least a part of the common power connection line is exposed, and the second routing line may be in contact with the common power connection line in the third contact area. The third contact area may be disposed outside the dam structure.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate including a display area and a non-display area adjacent to the display area;
a pixel disposed in the display area of the substrate, the pixel including at least one transistor and a light emitting diode;
a touch sensor unit disposed on the pixel, the touch sensor unit including at least one touch electrode;
a common power line disposed in the non-display area of the substrate and electrically connected to the light emitting diode; and
a gate driving circuit disposed in the non-display area of the substrate,
wherein the common power line and the gate driving circuit overlap each other in at least a part of the non-display area.

2. The display apparatus according to claim 1, wherein the non-display area includes:
a first non-display area disposed at a first edge of the substrate;
a second non-display area disposed at a second edge of the substrate opposing the first non-display area;
a third non-display area disposed at a third edge of the substrate; and
a fourth non-display area disposed at a fourth edge of the substrate opposing the third non-display area.

3. The display apparatus according to claim 2, wherein the gate driving circuit is disposed in the third non-display area and the fourth non-display area,
wherein the common power line is disposed in a part of the first non-display area and in the second to fourth non-display areas, and
wherein the gate driving circuit and the common power line overlap each other in at least one of the third non-display area and the fourth non-display area.

4. The display apparatus according to claim 3, wherein the touch sensor unit includes:
a touch electrode part including at least one touch electrode;
a first routing part including a first routing line disposed in a part of the first non-display area and in the second to fourth non-display areas; and
a second routing part including a second routing line disposed in a part of the first non-display area and in the second to fourth non-display areas,
wherein the second routing line overlaps the common power line from a plan view.

5. The display apparatus according to claim 4, wherein the gate driving circuit and the second routing line overlap each other in at least one of the third non-display area and the fourth non-display area.

6. The display apparatus according to claim 4, wherein the second routing line is disposed outside the first routing line.

7. The display apparatus according to claim 2, further comprising:
a dam structure disposed in the first to fourth non-display areas and outside the gate driving circuit and the common power line.

8. The display apparatus according to claim 2, further comprising:
a pad part disposed in the first non-display area,
wherein the common power line is electrically connected to the pad part to receive a common power voltage.

9. The display apparatus according to claim 2, wherein the gate driving circuit is disposed on the same layer as the at least one transistor.

10. The display apparatus according to claim 2, further comprising:
a planarization layer disposed on the at least one transistor;
an interlayer insulating layer disposed on the planarization layer; and
a bank layer disposed on the interlayer insulating layer and defining a pixel area of the pixel and an opening area inside the pixel area,
wherein the light emitting diode includes:
a first electrode disposed on the interlayer insulating layer and electrically connected to the at least one transistor through a first contact hole penetrating through the interlayer insulating layer and the planarization layer;
an emission layer disposed on the first electrode and being in contact with the first electrode in the opening area; and
a second electrode disposed on the emission layer.

11. The display apparatus according to claim 10, further comprising:
a common power connection line disposed on the interlayer insulating layer in the non-display area,
wherein the second electrode is in contact with the common power connection line through a second contact hole penetrating through the bank layer in the non-display area.

12. The display apparatus according to claim 11, wherein the common power connection line is in contact with the common power line through a third contact hole penetrating through the interlayer insulating layer in the third non-display area and the fourth non-display area.

13. The display apparatus according to claim 12, further comprising:
an encapsulation layer extending to the non-display area while covering the pixel in the display area; and
a dam structure disposed in the non-display area.

14. The display apparatus according to claim 13, wherein the touch sensor unit includes:
a first touch electrode and a second touch electrode disposed on the encapsulation layer in the display area;
a first routing line disposed on the encapsulation layer in the non-display area; and
a second routing line disposed on the encapsulation layer and outside the first routing line in the non-display area.

15. The display apparatus according to claim 14, wherein the second routing line extends to a first contact area in the first non-display area, wherein in the first contact area, at least a part of the common power line is exposed, and the second routing line is in contact with the common power line in the first contact area,
wherein the first contact area is disposed outside the dam structure.

16. The display apparatus according to claim 14, wherein the second routing line extends to a second contact area in the second non-display area, wherein in the second contact area, at least a part of the common power line is exposed, and the second routing line is in contact with the common power line in the second contact area, and
wherein the second contact area is disposed outside the dam structure.

17. The display apparatus according to claim 2, wherein the gate driving circuit is disposed in the third non-display area and the fourth non-display area,
wherein the common power line is disposed in a part of the first non-display area and in the third and fourth non-display areas, and
wherein the gate driving circuit and the common power line overlap each other in at least one of the third non-display area and the fourth non-display area.

18. The display apparatus according to claim 14, wherein the second routing line extends to a third contact area in the second non-display area,
wherein in the third contact area, at least a part of the common power connection line is exposed, and the second routing line is in contact with the common power connection line in the third contact area, and
wherein the third contact area is disposed outside the dam structure.

19. The display apparatus according to claim 11, wherein the common power connection line is disposed to overlap at least a part of the gate driving circuit and the common power line from a plan view.

20. The display apparatus according to claim 19, wherein the common power connection line is disposed in the third non-display area and the fourth non-display area to overlap the gate driving circuit and the common power line from a plan view.
